(19) United States
(12) Patent Application Publication
(10) Pub. No.: US 2007/0261956 A1
(43) Pub. Date: Nov. 15, 2007

(54) COATING INSTALLATION WITH CARRIER FOR SUBSTRATE COATING

(75) Inventor: Juergen ULRICH, SCHOENCK (DE)

Correspondence Address: PATTERSON & SHERIDAN, L.L.P., 3040 POST OAK BOULEVARD, SUITE 1500, HOUSTON, TX, 77056, US

(73) Assignee: APPLIED MATERIALS GMBH & CO. KG, ALZENAU (DE)

(21) Appl. No.: 11/746,749

(22) Filed: May 10, 2007

(30) Foreign Application Priority Data
May 12, 2006 (EP) 06009859.7

(51) Int. Cl. C23C 14/00; C23C 16/00

(52) U.S. Cl. 204/298.15; 118/728

(57) ABSTRACT

The present invention concerns a coating installation with a substrate carrier that consists essentially of a plate made from glass-ceramic. Glass-ceramic material is less expensive and has a shorter delivery time than CFC material conventionally used so far. The coating installation can thus be operated more economically.

### BACKGROUND

1. Field of the Invention

The present invention concerns a coating installation for coating substrates and the use of a material for a substrate carrier for coating substrates.

2. Background of Invention

Coating installations for substrate coating, especially coating installations for the production of solar cells by means of vacuum deposition methods, such as PVD (physical vapor deposition), usually have a substrate carrier that is adapted to accommodate one or more substrates, e.g. silicon wafers. Such a substrate carrier not only serves to accommodate and transport the substrates inside the coating installation, it also acts as a carrier for the substrates during coating, and so the substrate carrier has to satisfy various requirements regarding its material properties.

For one thing, it may not be a material that diffuses into the substrate during heating. Further, the material must be heat-resistant and undergo only minor thermal expansion. Finally, a combination of high modulus of elasticity, that is, high rigidity, and low density is needed in order that the substrate carrier may essentially undergo no warpage and the transport device of the coating installation need only have small dimensions for the substrate carrier.

Usually, substrate carriers have hitherto consisted of a fiber-reinforced composite, especially a carbon fiber reinforced carbon (CFC), since this has a low specific weight, a very high rigidity, even at very high temperatures, and low thermal expansion.

The disadvantage of such a substrate carrier, however, is the high costs and the long delivery times, which are to due to the CFC material. Moreover, not even CFC substrate carriers are always free of warpage during heating.

The object of the present invention is therefore to provide a coating installation which has a low-warpage substrate carrier that permits more economical, especially less expensive use of the installation. The substrate carrier is to be manufactured simply and economically.

This object is achieved by a coating installation in accordance with claim 1 and the use of a material for a substrate carrier in accordance with claim 15. Advantageous embodiments are the subject of the dependent sub-claims.

### SUMMARY OF THE INVENTION

The inventive coating installation, which especially finds application in the production of solar cells, comprises a substrate carrier for coating substrates that essentially consists of a glass-ceramic material. Glass-ceramic materials are heat-resistant and have by nature a high modulus of elasticity combined with low density and a low thermal expansion, with the temperature dependence of the modulus of elasticity being lower than that of a CFC material, so that less warpage is ensured during heating. Moreover, this relatively inexpensive material can be processed simply, so that the substrate carrier can be made inexpensively and thus the coating installation can be operated economically.

Schott Robax® material is used particularly advantageously as glass-ceramic material. This material has so far been used particularly for the construction of transparent fire partition, for example, for oven doors, and is extremely heatproof and has a very low thermal expansion. This commercially available material is only about half as expensive as CFC material and is deliverable in a much shorter time. Alternatively, NeoCeram® N-11 material from Nippon Electric Glass Co. Ltd., which has properties similar to Schott Robax® material, may also be used.

Preferably, the substrate carrier is designed as an essentially rectangular plate and has on one principal face several adjacent receptacles for accommodating substrates. This means that several substrates can be coated at the same time.

Especially preferred in this connection is that the receptacles are formed as recesses in the substrate carrier, because that makes the substrate carrier particularly easy to produce. If the individual substrate receptacles are then separated from each other by strip-like bars and the substrate carrier has an outer bar-like edge limiting the outer receptacles, many substrates can be accommodated, relative to the substrate carrier surface, with the substrate carrier retaining sufficient rigidity and stability.

In order that stresses may be avoided at the transition points among the strip-like bars, the individual side areas of the edge or the strip-like bars and the outer edge, rounded transitions are provided there, such that the edges of the strip-like bars do not contact one another at right angles or the strip-like bars do not contact the edge at right angles.

Preferably, the transitions are implemented as semi-circles that extend tangentially from a strip-like bar or from a side area and merge into the strip-like bar or side area of the respective receptacle running at right-angle to this.

In an advantageous further embodiment, the substrate carrier is formed of several pieces, with the substrate carrier preferably being separably formed along the strip-like bars with the help of the side strips connecting the individual parts, such that for one thing, depending upon the need and size of the coating installation, the number of the accommodatable substrates can be simply adapted and, for another, the entire substrate carrier does not have to be replaced, but rather only part of it, in the event of damage to the substrate carrier. This increases the economics even further.

Advantageously, recessed supports for the substrates are arranged in the receptacles. With supports implemented as relief cut, for example, both lying accommodation of the substrates and virtually perpendicular accommodation can be guaranteed (5°-10° inclination of the substrate carrier to the perpendicular), since falling out of the substrates from the substrate carrier is effectively prevented in the case of recessed supports having such an inclination. If access openings are provided in the receptacles, the substrates can be handled more easily. Especially, the supports can then be formed as opposing U-shaped grooves on two sides of the receptacles, the inner arcs of said grooves being aligned with the substrate carrier plane, with the distance between the inner arcs of the opposing U-shaped grooves in one receptacle being greater, and the distance between the outer ends of the opposing U-shaped grooves in a receptacle being smaller, than the lateral dimension of the substrate. In this regard, the grooves are arranged opposingly in the direction in which the substrate carrier is to be perpendicularly placed, with the distance between the inner arc of the upper groove, relative to the perpendicularly placed substrate carrier, and an outer end of the opposing groove being greater than the lateral dimension of the substrate. In this way, a substrate, in an orientation slightly inclined to the perpendicular, can be introduced into an upper groove, relative to the perpendicular position of the substrate carrier, and, after being swiveled into the perpendicular, can be set down into the lower groove, with the outer ends of the upper and lower grooves now holding the substrate in the receptacle. The distances between the ends and arcs need only be slightly (several millimeters) greater or smaller than the lateral dimension of the substrate. Due to the smaller distance between the ends of the grooves, relative to the lateral dimension of the substrate, secure laying accommodation of the substrate is possible.

If, now, those outer ends at least of the opposing U-shaped grooves in a receptacle which face the coating source are partially perforated, only very slight shadowing of the substrate occurs during coating.

Independent protection is sought for the use of a glass-ceramic material for a substrate carrier, which is especially formed according to the above specifications. It is preferable in this regard if the commercially available Schott Robax® material or NeoCeram® material N-11, a glass ceramic consisting of a glassy and a crystalline structure is used for the glass-ceramic material since these can be procured more economically and at shorter notice than comparable materials, especially CFC.

### BRIEF DESCRIPTION OF THE DRAWINGS

Further features, characteristics and advantages of the present invention result from the following description of a preferred embodiment shown in the drawing. These show in

FIG. 1 is a plan view of a substrate carrier;

FIG. 2 is a magnified area of the substrate carrier from FIG. 1 and;

FIG. 3 a magnified area of the substrate carrier from FIG. 2 and;

FIG. 4 a cross-sectional view of the magnified area from FIG. 2.

### DETAILED DESCRIPTION

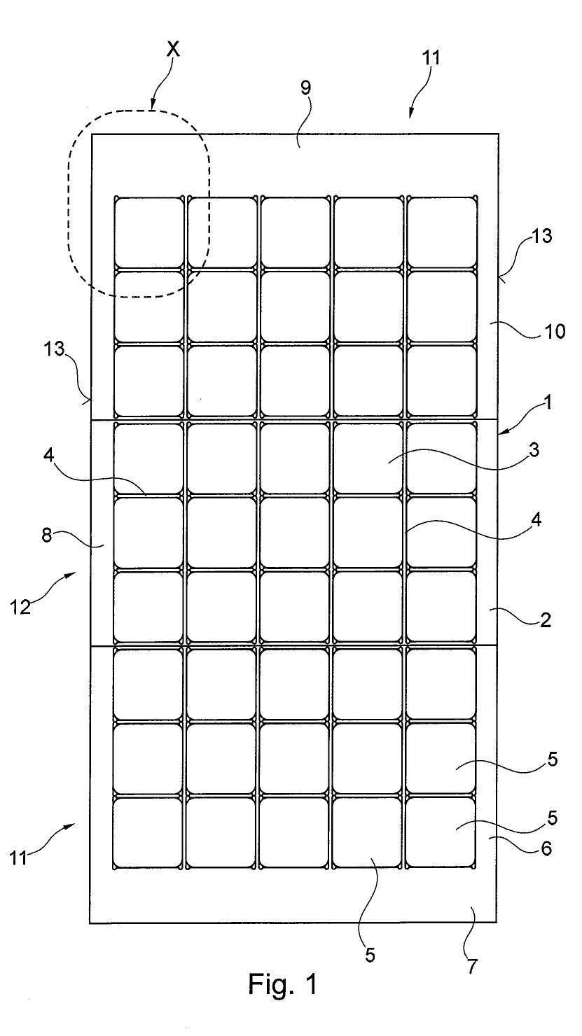

FIG. 1 is a purely schematic, plan view of a substrate carrier 1 in a preferable embodiment of the present invention. The substrate carrier 1 consists of a multipart Schott Robax® glass-ceramic plate 2, which has a basic rectangular shape and in which several receptacles 3, 5 are arranged in chessboard-like fashion. The receptacles 3 are separated by strip-like, vertically projecting bars 4. The outer receptacles 5 are each surrounded by an outer edge 6, which projects vertically in relation to the recessed receptacles 3, 5, and which has four boundary regions 7, 8, 9, 10 corresponding to the four sides of the rectangular plate 2, with the boundary regions 8, 10 extending along the full length of the substrate carrier 1.

As will become clear in the following, due to missing material of the substrate carrier 1 in the receptacles 3, 5, the substrate carrier 1 is formed relatively easily on one hand and has sufficiently high rigidity due to the bars 4 and the heightened edge 6. Additionally, it can be made particularly simply, for example, by milling a commercially available Robax® plate.

The substrate carrier 1 is multi-part, namely formed of three parts, and consists of two side parts 11 and a center section 12. The individual parts 11, 12 of the substrate carrier 1 are connected along bars 4, such that two bars 4 lay against each other in each transition area. The individual parts 11, 12 are connected by strips 13, which are each connected to the parts 11, 12, for example by one or more screw connections. Naturally, other detachable connections, for example along the adjacent bars 4 of the individual parts 11, 12, are possible. Likewise, the parts 11, 12 can be bonded, especially ceramically, to each other or to the strip 13 if the functionality of detachability can be dispensed with.

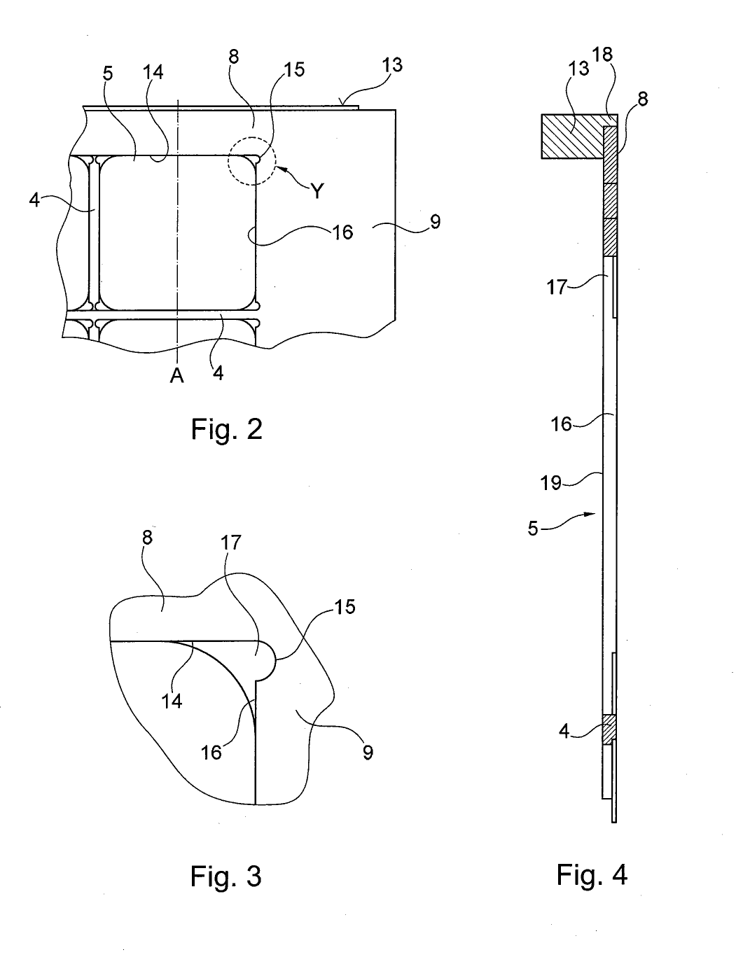

FIG. 2 shows a magnification of the area marked X in FIG. 1. It may be seen that the transition area between the boundary regions 8, 9 is rounded such that the edge 14 of the boundary region 8 pointing to receptacle 5 merges tangentially into a semicircular transition 15 and the transition 15 in turn merges perpendicularly into the edge 16 of the boundary region 9 pointing to receptacle 5. The transition 15 is even clearer in the further magnified illustration of the area Y in FIG. 3, with it being evident that the transition 15 does not completely extend through the receptacle 5, but rather the receptacle 5 has a support 17 for the substrates, which is formed by an arc-shaped element in the form of a relief cut. The transition 15 is thus limited in the accommodation direction by the support 17.

Through the transition 15, perpendicular contacting of the edges 14, 16 of the boundary regions 8, 9 is prevented, a fact which contributes to the reduction or prevention of especially heat-related stresses in this transition area.

In opposition to this arrangement, the transition 15 can also merge tangentially into the edge 16 and contact the edge 14 perpendicularly. Likewise expedient is a transition merging tangentially into both edges 14, 16, said transition being formed for example as a quarter circle.

Such semicircular transitions 15 and the supports 17 limiting them in the accommodation direction are likewise provided at the transition areas between the individual boundary regions 7, 8 and 8, 9 and 9, 10 as well as 7 and also among themselves in the transition areas between the edge 6 and the bars 4 as well as between the bars 4. Of course, provision can also be made for such stress relief transitions not to be formed at all points of crossing.

Finally, FIG. 4 shows a cross-sectional view of the substrate carrier 1 along the line A in FIG. 2, with a view of the edge 16.

Clearly recognizable is the strip 13, which interconnects the three parts 11, 12 of the substrate carrier, with the parts 11, 12 resting against an edge bar 18 in a recess of the strip 13.

The height of the recesses of the supports 17 in the receptacles 3, 5 is adjusted to the thickness of the substrates such that the coating of the substrates is not impaired by shadowing effects caused by, for example, the edge 6 and the bars 4.

The support 17 of the receptacles 3, 5 is provided with a central opening 19, which facilitates handling of the substrates placed in the receptacle 3,5 due to an access opening. The support 17, however, can also be formed continuously as a peripheral relief-cut edge, especially to increase the stability of the support 17 and the entire substrate carrier 1.

From the present description, it has become clear that a substrate carrier can be manufactured from glass ceramic very simply and more economically than from common CFC material. Since, moreover, the glass-ceramic material, for example the preferred Schott Robax® material, has a substantially shorter delivery time, coating installations can be operated much more economically. Also, simply retrofitting of existing installations is possible.

1. Coating installation, especially for the production of solar cells, comprising a substrate carrier for coating substrates, wherein the substrate carrier essentially consists of a glass-ceramic material.

2. The coating installation of claim 1, wherein the substrate carrier essentially consists of Schott Robax® material or NeoCeram® N-11 material.

3. The coating installation of claim 1, wherein the substrate carrier is designed essentially as a rectangular plate and has on one principal face several adjacent receptacles for accommodating substrates adjacent each other.

4. The coating installation of claim 3, wherein the receptacles have recesses in the substrate carrier.

5. The coating installation of claim 4, wherein the receptacles are separated by strip-like bars and the substrate carrier has an outer bar-like edge limiting the outer receptacles.

6. The coating installation of claim 5, wherein transition points among the strip-like bars, the individual side areas of the edge or the strip-like bars and the outer edge have rounded transitions, such that neither the edges of the strip-like bars nor the edges of the edge regions or those of the strip-like bars and the edge regions make contact at right angles.

7. The coating installation of claim 6, wherein the transitions are implemented as semi-circles that extend tangentially from a strip-like bar or from an edge area and merge into the strip-like bar or edge area of the respective receptacle running at right-angles to this.

8. The coating installation of claim 5, wherein the substrate carrier is multi-part.

9. The coating installation of claim 8, wherein the substrate carrier is separably formed along the strip-like bars.

10. The coating installation in accordance with claim 9, wherein the individual parts of the substrate carrier are interconnected by side strips.

11. The coating installation of claim 3, wherein the receptacles have recessed supports for the substrates.

12. The coating installation of claim 3, wherein the receptacles have access openings.

13. The coating of claim 12, wherein the supports can then be formed as opposing U-shaped grooves on two sides of the receptacles, the inner arcs of said grooves being aligned with the substrate carrier plane, with the distance between the inner arcs of the opposing U-shaped grooves in one receptacle being greater, and the distance between the outer ends of the opposing U-shaped grooves in a receptacle being smaller, than the lateral dimension of the substrate, with the distance between the inner arc of one groove and an outer end of the opposing groove being greater than the lateral dimension of the substrate.

14. The coating installation of claim 13, wherein at least of the opposing U-shaped grooves in a receptacle which face the coating source are partially perforated, shadowing of the substrate during coating is reduced.

15. Use of a glass-ceramic material for a substrate carrier for coating substrates

16. The use of claim 15, wherein the substrate carrier essentially consists of a glass ceramic material.

17. The use of claim 15, wherein the glass ceramic material is Schott Robax® material or Neo-Ceram® N-11 material.
